(19) United States
(12) Patent Application Publication
(10) Pub. No.: US 2013/0334648 A1
(43) Pub. Date: Dec. 19, 2013

(54) Methods and Apparatus for High Voltage Diodes

(71) Applicants: Wan-Yen Lin, Kaohsiung City (TW); Yi-Feng Chang, Xinbei City (TW); Jam-Wem Lee, Zhubei City (TW)

(72) Inventors: Wan-Yen Lin, Kaohsiung City (TW); Yi-Feng Chang, Xinbei City (TW); Jam-Wem Lee, Zhubei City (TW)

(73) Assignee: TAIWAN SEMICONDUCTOR MANUFACTURING COMPANY, LTD., Hsin-Chu (TW)

(21) Appl. No.: 13/524,902

(22) Filed: Jun. 15, 2012

(51) Int. Cl. H01L 29/861; H01L 21/329

(52) U.S. Cl. 257/493; 438/439; 257/E29.327; 257/E21.352

(57) ABSTRACT

High voltage diodes are disclosed. A semiconductor device is provided having a P well region; an N well region adjacent to the P well region and forming a p-n junction with the P well region; a P+ region forming an anode at the upper surface of the semiconductor substrate in the P well region; an N+ region forming a cathode at the upper surface of the semiconductor substrate in the N well region; and an isolation structure formed over the upper surface of the semiconductor substrate between the anode and the cathode and electrically isolating the anode and cathode including a first dielectric layer overlying a portion of the upper surface of the semiconductor substrate, and a second dielectric layer overlying a portion of the first dielectric layer and a portion of the upper surface of the semiconductor substrate. Methods for forming the devices are disclosed.

### BACKGROUND

As semiconductor process nodes continue to advance using smaller and smaller minimum feature sizes, advanced high voltage (“HV”) diodes continue to be needed. Existing HV diode designs require significant semiconductor area, and area is a critical characteristic as integrated circuit devices continue to add functionality and become increasingly highly integrated.

HV diodes are used in many integrated circuits. Because diodes provide a rectifier or “one way” current path, the HV diodes are typically used at input/output pins of integrated circuits, for example. The diodes can prevent current and voltage damage to the interior circuitry by preventing the conditions at the external pin from disturbing the interior circuitry, while still allowing output current to flow, for example, from drivers in the integrated circuit to the external pin. Other applications include high voltage driver applications such as automotive, linear and power applications, as well as input/output circuitry, and in other circuitry.

Existing HV diodes have on-currents that are lower than desirable per unit of semiconductor area, resulting in a higher than desired forward resistance. To use the existing HV diodes and achieve the needed forward resistance, too much area is required. Improved HV diodes that are compatible with current and future advanced semiconductor processes are therefore needed.

### BRIEF DESCRIPTION OF THE DRAWINGS

For a more complete understanding of the illustrative embodiments, and the advantages thereof, reference is now made to the following descriptions taken in conjunction with the accompanying drawings, in which:

FIG. 1 depicts in a cross-sectional view an illustrative embodiment;

FIG. 2 depicts in a cross-sectional view another embodiment;

FIG. 3 depicts in a circuit diagram a typical application including an HV diode;

FIG. 4 depicts in an I-V plot diagram the current-voltage characteristics for HV diodes using the embodiments;

FIG. 5 depicts in a table the performance metrics for the HV diodes of the embodiments and a comparative example; and

FIG. 6 depicts an embodiment method in a flow diagram.

Corresponding numerals and symbols in the different figures generally refer to corresponding parts unless otherwise indicated. The figures are drawn to clearly illustrate the relevant aspects of the described illustrative embodiments and are not necessarily drawn to scale.

### DETAILED DESCRIPTION

The making and using of illustrative example embodiments are discussed in detail below. It should be appreciated, however, that an illustrative embodiment provides many applicable inventive concepts that can be embodied in a wide variety of specific contexts. The embodiments herein are illustrative examples but do not limit the scope of the disclosure, and do not limit the scope of the appended claims.

In the embodiments, HV diode structures are formed using isolation approaches that include forming dielectric layers over the substrate. In example embodiments, resurf oxide layers (“ROX”) and resistance protective oxide (“RPO”) layers are formed overlying the substrate; although other dielectrics may be used that overlie the substrate. By using these isolation structures between the cathode and anode regions, the current flowing in an on-state for the diodes in the embodiments is allowed to flow on and near the surface of the semiconductor substrate, and thus, the HV diodes of the embodiments have lowered on-resistance when compared to the on-resistance in existing HV diode structures using existing shallow trench isolation (STI) structures.

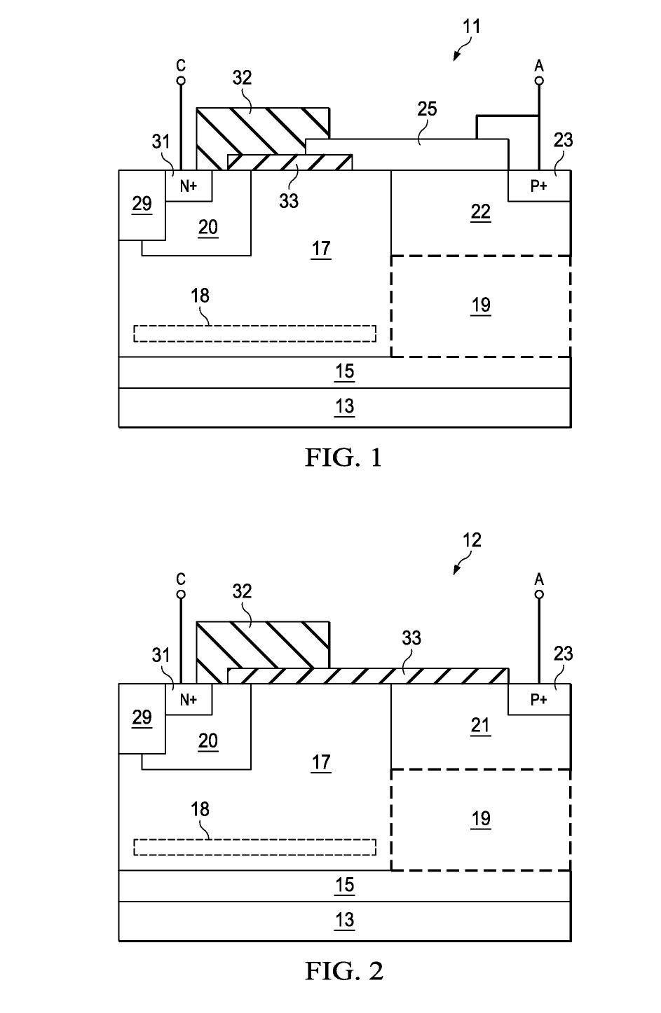

FIG. 1 depicts in a cross sectional view an example embodiment of a HV diode structure 11. In FIG. 1, a portion of a semiconductor substrate 13 is depicted. Semiconductor substrate 13 may be an N-type or P-type doped substrate, and may be formed from silicon, gallium arsenide, or other known semiconductor materials used in semiconductor device processing. Although in the illustrated examples presented a semiconductor substrate is used, in other example embodiments epitaxially grown semiconductor materials may be used, or, silicon on insulator (“SOI”) layer may be used as the substrate 13. While the semiconductor substrate may be doped with either N-type or P-type impurities, in the examples presented herein the substrate 13 is a P-type substrate.

As shown in FIG. 1, in this non-limiting example an N-type buried layer (NBL) 15 is provided to isolate the high voltage structure 11 from the remainder of the substrate. While not visible in the cross section of FIG. 1, NBL layer 15 may surround the entire diode structure and isolate it from the remainder of the substrate 13.

A first N-type doped well region 17 is formed within the semiconductor substrate 13 forming a high voltage N well (“HVNW”). A second doped well region 19 is formed in the semiconductor substrate 13 and doped to a P-type well, forming a high voltage P well (“HVPW”). The well region 19 is formed proximate to and adjacent to the well region 17 and the common boundary of the well regions 17 and 19 forms a p-n junction of the HV diode structure 11.

Dopant impurities are implanted into the semiconductor material to form P+, and, P-type regions in semiconductor material, and N+ and N-type regions, as is well known. Dopant atoms for P-type regions include boron, for example. In N-type regions, dopant atoms include phosphorous, arsenic, and antimony, for example. Doping may be done by ion implantation processes. When coupled with photolithographic processes, doping may be performed in selected areas by implanting atoms into exposed regions while other areas are masked. Also, thermal drive or anneal cycles may be used to cause thermal diffusion to expand or extend a previously doped region. As alternatives, some epitaxial deposition of semiconductor materials allow for in-situ doping during the epitaxial processes. Ion implantation can be done through certain materials, such as thin oxide layers, as is known.

As shown in FIG. 1, the first well region 17 also has a deep doped region that is doped to a P-type to form a deep well (DPW) diffusion 18. N+ region 31 is formed in the upper surface of the substrate in the well region 17. This N+ region 31 is highly doped to form a cathode for the diode, and is disposed at the surface of the substrate 13 to allow an electrical contact to be made to couple the cathode to other circuit elements. In FIG. 1 a terminal labeled “C” is coupled to the cathode 31. The N+ region 31 is disposed within another N-type doped region 20, which forms a shallow N-well (SHN).

A P+ region 23 is formed at the surface of the substrate 13 and forms an anode for the diode 11, which is shown coupled to a terminal labeled “A” in FIG. 1. The P+ region is disposed in the P well region 19 that forms a high voltage P well (HVPW) and is further disposed within another P-type doped region 22, which forms a shallow P well (SHP). P+ region 23 forms an anode contact for coupling to an anode terminal for the diode. The shallow N-well region (SHN) region 30 has an anode side boundary that is spaced from the p-n junction, so that a portion of the HVNW 17 is exposed at the surface of the substrate 13. The SHP region 22 covers the HVPW 19, which is not exposed at the surface of the substrate 13.

The HVNW 17 and HVPW 19 regions, along with the P-type region SHP 22, form p-type and n-type regions that are adjacent, and thus form a p-n junction for the diode 11. When a forward bias is applied to the anode, current can flow in the diode, however, the diode will resist current flow in the other direction, therefore in circuits the HV diode often is used for providing a protective function. The HV diodes of the embodiments may be used in many circuit applications in integrated circuits.

The cathode and anode of the diode 31, 23 and the surrounding regions need to be electrically isolated from one another. In FIG. 1, several structures are shown overlying the upper surface of substrate 13 and the p-n junction between the p regions P well 19 and SHP 22, and the n region HVNW 17, to provide the cathode to anode isolation for the diode 11.

A dielectric or insulating layer 33 is shown formed over the substrate. This oxide is, in one example embodiment, an oxide, nitride or oxynitride layer that forms a RESURF oxide (ROX), a reduced surface field effect oxide layer. The ROX 33 may be formed using various known approaches for the deposition of oxides, nitrides or oxynitrides over a substrate surface. Other insulator layers may be used to form additional alternative embodiments.

A second insulator 32 is shown. In the example embodiments, in addition to the ROX layer 33, a resist protect oxide (RPO) 32 is formed overlying a portion of the ROX layer 33, and, overlying a portion of SHN well 20. Resist protect oxides may be formed as described in, for example, U.S. Pat. No. 6,348,389, which is hereby incorporated by reference herein in its entirety. The RPO layer 32 may be formed of an oxide, a nitride, an oxynitride, and multiple layers may be used to form the RPO layer as is known. Other insulators or dielectrics may be used for layer 32 and these alternatives form additional alternative embodiments.

In the embodiment of FIG. 1, an optional polysilicon layer 25 is formed over the p-n junction formed between HVPW 19 (including SHP 22) and HVNW 17. The polysilicon 25 may be coupled to an anode terminal along with the anode contact region 23, as shown in FIG. 1 and may overlie a portion of the ROX layer 33 as depicted. In addition, in a semiconductor process that includes, for example, forming polysilicon logic gates, polysilicon 25 may be formed simultaneously with, and using the same materials as, polysilicon logic gates formed elsewhere on the semiconductor substrate (not shown). Gate dielectric layers (not shown) would be part of the logic gates and would also be formed underlying the polysilicon 25 if this approach is used.

Concentration amounts of dopant atoms after doping may vary from 1E16 to 1E1022 atoms/cm³, for example. N+ and P+ regions have the highest concentrations of dopant atoms, to form good electrical contact terminals for making connections, as is known. In the embodiments, the regions 17 and 19, the HVNW and HVPW regions are doped to a first dopant concentration for each well region. The DPW and SHP P-type regions 18, 22 are both doped to similar concentrations that are greater than the concentration of HVPW region 19; while the SHN and NBL regions 20, 15 are both doped to a concentration that is greater than the concentration of HVNW 17. The dopant concentrations used in a particular example depends on the semiconductor processes, the intrinsic concentration of atoms in the substrate chosen, and the device sizes fabricated, as example factors, and so may vary from application to application, all of these variations are within the scope of the claims and the embodiments.

The HV diode 11 of FIG. 1 will have substantially increased performance over the existing diode structures for HV applications, as is described further below. The on-current for a given area is increased by approximately 100% over existing HV diode structures. It is believed that the use of the ROX, RPO and polysilicon structures on the surface of the semiconductor substrate between the cathode ‘C’ of FIG. 1 and the anode “A” allow current to flow on or at the surface of the substrate, increasing the on-current. The current in the existing HV diodes using STI isolation structures, or other isolation structures, require the current path to extend deep downwards into P and N well regions, increasing the length of the current path and increasing the resistance, thus reducing the on-current. Accordingly the performance of the HV diodes of the embodiments is substantially improved over prior approaches.

FIG. 2 depicts in a cross sectional view an alternative embodiment of an HV diode 12. In FIG. 2 many of the elements are the same as FIG. 1 and like reference numerals are used for like elements, and for some of the elements, no further description is provided.

In the embodiment HV diode structure 12 of FIG. 2, as illustrated the semiconductor substrate 13 is again provided with an N well 17 and a P well 19, with SHN 20, and SHP 21; and a N+ region 31 provides a cathode for the diode, while a P+ region 23 provides an anode. The ROX layer 33 now extends from the SHN 20 overlying the p-n junction between the two well regions, and to the edge of the P+ region 23. The RPO layer 32 is provided overlying the ROX region 33.

In the embodiment of FIG. 2, the features are similar to the embodiment of FIG. 1, except that the polysilicon region 25 of FIG. 1 is omitted. While the polysilicon region 25 may be used with the embodiments as in FIG. 1, in some applications under a high voltage event at the cathode (reverse bias), for example, the thin gate dielectric underlying the gate polysilicon 25 in FIG. 1 could fail or rupture. Thus in the HV diode 12, the alternative embodiment of FIG. 2, the polysilicon gate material is not used, instead the ROX layer 33 is extended and overlies the p-n junction and provides isolation between the cathode and the anode terminals.

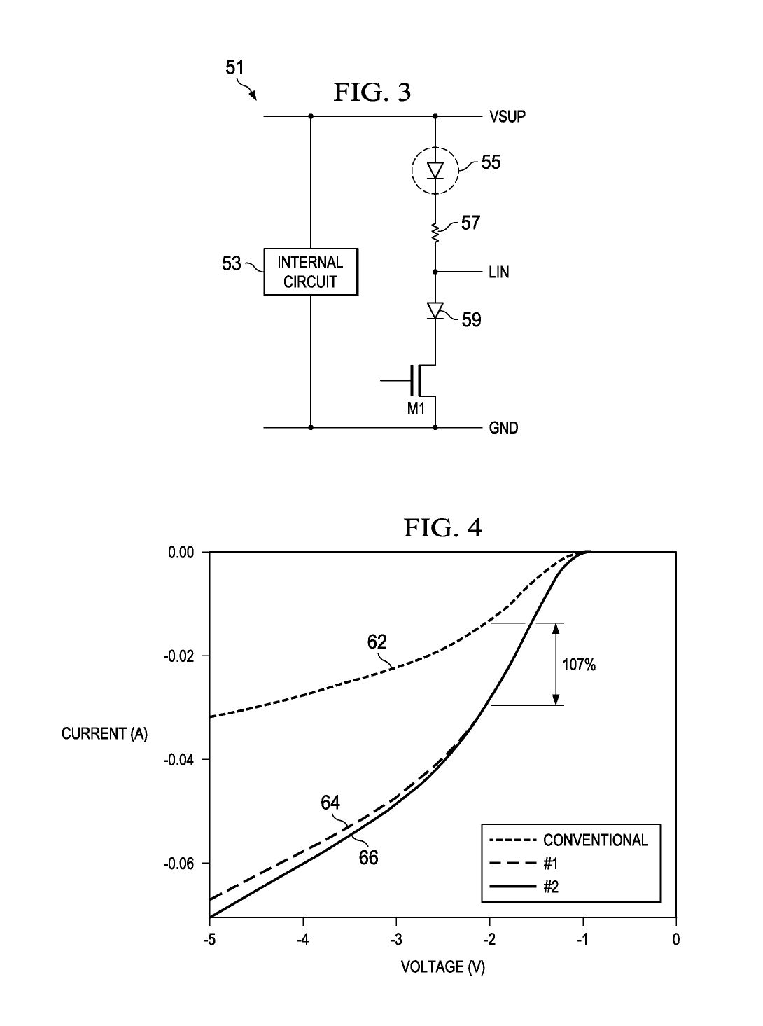

The HV diode embodiments described above may be used in any application where HV diodes are used. FIG. 3 depicts a simple example of an application for an input/output terminal for an automotive type circuit. In this circuit, a terminal LIN is pulled down, for example, when transistor M1 is active. The HV diode 55 may be formed using either embodiment shown above, either the embodiment of FIG. 1, or the embodiment of FIG. 2. Resistors 57 and diode 59 provide bias and current control for the circuit 51. Normally when the diode 55 is operating in the forward bias condition, it supplies current to the terminal LIN or through transistor M1 to ground. If a high voltage is applied over the voltage VSUP at the terminal LIN, the HV diode will prevent current from flowing into the circuitry, preventing damage to the internal circuit 53 for example.

FIG. 4 depicts the performance of the HV diodes of the embodiments in a plot illustrating a portion of the current-voltage (I-V) characteristic for the embodiments, and for a comparative example of an existing HV diode structure. In FIG. 4, the existing HV diode is plotted as trace 62, the first embodiment shown in FIG. 1 is plotted as trace 64, and the second embodiment of FIG. 2 is plotted as trace 66. In FIG. 4, all three of the diodes turn on at around 1 volt and begin current conduction. At around 2 volts, the embodiment diodes, which are the lower traces 64 and 66 in the plot, exhibit current of about twice the current of the comparative example diode, that is, an improvement is shown of over 100% at about 2 volts in the on-current characteristic. This is indicated by the double ended arrow in the figure, showing a change of a 107% increase in the on-current for the embodiments of FIGS. 1 and 2 over the comparative example, at the 2 Volts point.

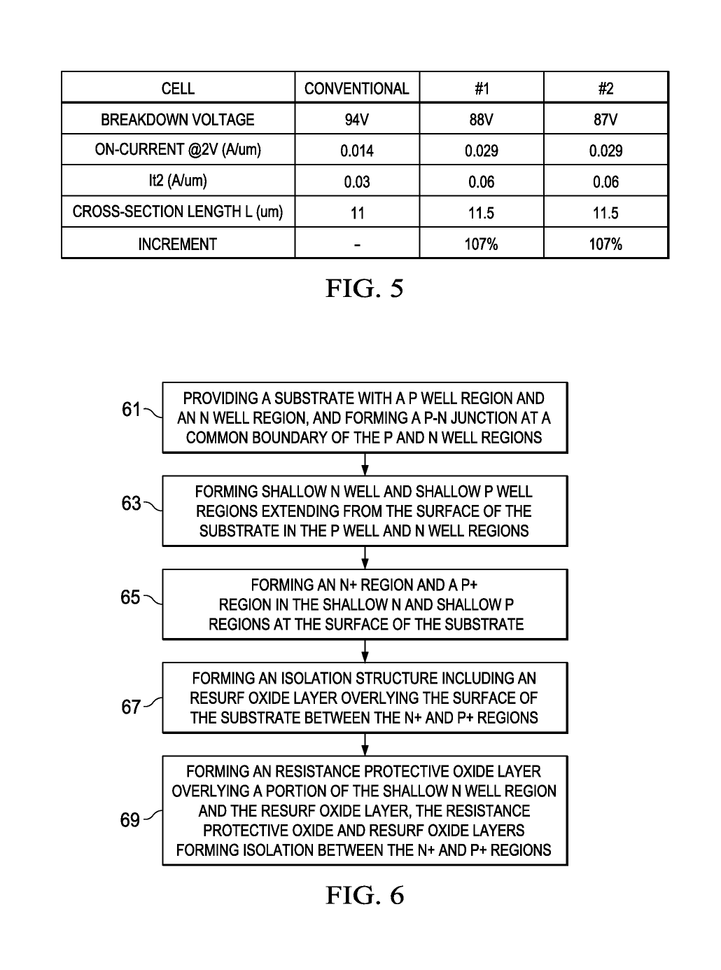

FIG. 5 depicts additional comparative information illustrating the advantages of the embodiments. In FIG. 5, a conventional HV diode structure, including for example STI isolation between the anode and cathode terminals, is compared to the embodiment of FIG. 1, labeled #1 and the embodiment of FIG. 2, labeled #2, for several performance metrics. The on-current for the embodiments, as described above and shown in FIG. 4, is greatly increased by use of the embodiments. The breakdown voltage, that is, the voltage at which a reverse biased diode “breaks down” and allows current to flow in the reverse direction is decreased slightly from the existing approach by use of the embodiments, yet remains very high, 88 and 87 volts for typical examples in an advanced semiconductor process. A measure of diode resistance is It2, that is, the current per unit area. As shown in FIG. 5, the current per square micron (um²) is approximately twice that of the conventional diode, put another way, the forward resistance is substantially lower for HV diodes using the embodiments as described above, allowing for smaller device sizes to provide adequate performance, saving semiconductor area. In the examples of FIG. 5, the devices had a similar size that is 11 ums in length for the existing prior approach device, and 11.5 ums for the two embodiment devices.

FIG. 6 depicts in a simple flow diagram a method embodiment. In state 61, a substrate is provided and has a P well region and an N well region, forming a p-n junction at a common boundary of the P and N well regions. In state 63, a shallow N well and shallow P well region is formed extending into the substrate in the P and N well regions. In state 65, an N+ region is formed in the shallow N well region and a P+ region is formed in the shallow P well region. In state 67 an isolation structure is formed including an ROX layer between the N+ and P+ regions, which as described above form an anode and a cathode for a diode. In state 69 an RPO layer is formed overlying a portion of the shallow N well region and the ROX layer, and forming isolation between the N+ and P+ regions.

In the embodiments a HV diode anode terminal is formed of a P+ doped region, a HV region, disposed in a HVPW region, and the cathode side of the diode may be formed of an N+ contact region, a SHN region, a HVNW region, and a DPW region. The device is surrounded by a buried layer, which an N type buried layer for example. The isolation between the anode and cathode regions may be, for example, ROX, RPO and may include a gate polysilicon region. In selected embodiments, the gate polysilicon may be omitted.

In an embodiment, a semiconductor device includes a P well region disposed within a semiconductor substrate having an upper surface; an N well region disposed within the semiconductor substrate adjacent to the P well region and forming a p-n junction with the P well region; a P+ region forming an anode at the upper surface of the semiconductor substrate in the P well region; an N+ region forming a cathode at the upper surface of the semiconductor substrate in the N well region; and an isolation structure formed over the upper surface of the semiconductor substrate between the anode and the cathode and electrically isolating the anode and cathode; wherein the isolation structure further comprises a first dielectric layer, which in one example, is an resurf oxide layer (ROX) overlying a portion of the upper surface of the semiconductor substrate, and a second dielectric layer, which may be for a non-limiting example, resist protect oxide layer (RPO), overlying a portion of the ROX layer and a portion of the upper surface of the semiconductor substrate.

In a further embodiment, in the above described semiconductor device the P well region further includes a shallow P well region disposed at the upper surface of the semiconductor substrate surrounding the P+ region. In another embodiment, in the above described semiconductor device the N well region further includes a shallow N well region disposed at the surface of the semiconductor substrate, surrounding the N+ region. In still another embodiment, in the above described semiconductor device, the device further includes a buried N-type layer disposed within the semiconductor substrate beneath the N well and P well regions.

In additional embodiments, the semiconductor device described above includes a deep P-type well region disposed proximate to the N-type buried layer and within the N well region. In another embodiment, in the above described semiconductor devices, the ROX layer extends over the upper surface of the semiconductor substrate from the shallow N well region in the N well region, over the p-n junction, and over the shallow P well region to a point proximal to the P+ region.

In still further embodiments, in the above described semiconductor devices the isolation structure further includes a polysilicon layer over the upper surface of the semiconductor substrate overlying the shallow P well region and the p-n junction. In still further alternative embodiments, the above semiconductor devices include wherein the polysilicon layer extends over the N well region and over a portion of the ROX layer. In yet further embodiments, in the above described semiconductor devices, the P well region has a first doping concentration of P-type atoms, the shallow P well region has a second doping concentration of P-type atoms, and the P+ region has a third concentration of P-type atoms, and the third concentration is higher than the second concentration, which is higher than the first concentration. In still another embodiment, in the above described semiconductor devices, the N well region has a first doping concentration of N-type atoms, the shallow N well region has a second doping concentration of N-type atoms, and the N+ region has a third concentration of N-type atoms, and the third concentration is higher than the second concentration which is higher than the first concentration.

In an alternative embodiment, a high voltage diode structure is provided that includes a P well region in a semiconductor layer having an upper surface; an N well region in the semiconductor layer, adjacent the P well region, and forming a p-n junction with the P well region; a P+ anode region at the upper surface of the semiconductor layer in the P well region; a shallow P well region in the P well region, the shallow P well region having a portion at the upper surface of the semiconductor layer, and surrounding the P+ anode region; an N+ cathode region at the upper surface of the semiconductor layer in the N well region; a shallow N well region in the N well region, the shallow N well region having a portion at the upper surface of the semiconductor layer, and surrounding the N+ anode region; and an isolation structure formed entirely over the upper surface of the semiconductor layer and overlying the p-n junction, the shallow P well region, and the shallow N well region.

In a further embodiment, in the high voltage diode structure described above, the isolation structure further includes: a resurf oxide (ROX) layer overlying the upper surface of the semiconductor layer between the P+ anode region and the N+ cathode region; and a resist protective oxide (RPO) layer overlying at least a portion of the ROX layer and a portion of the shallow N well region. In still another embodiment, the high voltage diode structure described above is provided wherein the ROX layer extends over the upper surface of the semiconductor layer from the N well region, over the p-n junction, and over at least a portion of the shallow P well region. In yet another embodiment, the high voltage diode structure of claim 11 is provided, wherein the isolation structure further comprises a polysilicon isolation feature formed overlying the upper surface of the semiconductor layer and extending from an area proximate the P+ anode over the shallow P well region, overlying the p-n junction, and overlying at least a portion of the N well region; a resurf oxide layer (ROX) overlying the upper surface of the semiconductor layer and extending from the shallow N well region towards the p-n junction, wherein a portion of the polysilicon isolation feature overlies a portion of the ROX layer; and a resist protect oxide (RPO) layer overlying the upper layer of the semiconductor layer and overlying at least a portion of the shallow N well region and overlying a portion of the ROX layer.

In still another embodiment, the above described high voltage diode structure is provided, wherein the polysilicon isolation feature further includes a gate polysilicon layer.

In yet another embodiment, a method includes providing a semiconductor layer having an upper surface; forming a P well in the semiconductor layer; forming an N well in the semiconductor layer adjacent the P well and forming a p-n junction with the P well; forming a shallow P-type well region in the P well, the shallow P-type well region having a portion at the upper surface of the semiconductor layer; forming a shallow N-type well region in the N well the shallow N-type well region having a portion at the upper surface of the semiconductor layer; forming a P+ anode at the surface of the semiconductor layer, surrounded by the shallow P-type well region; forming an N+ cathode at the surface of the semiconductor layer, surrounded by the shallow N-type well region; and forming an isolation structure between the anode and the cathode, the isolation structure overlying the upper surface of the semiconductor layer.

In still a further embodiment, the above described method is performed, wherein forming an isolation structure further includes forming a resurf oxide layer (ROX) overlying the upper surface of the semiconductor layer between the P+ anode and the N+ cathode; and forming a resist protect oxide (RPO) overlying a portion of the ROX layer and a portion of the shallow N well region. In still another embodiment, the above described method is performed, and further includes extending the ROX layer over the upper surface of the semiconductor layer from the shallow N well region over the p-n junction and over the shallow P-type nswell region to a position proximate the P+ anode.

In an additional embodiment, the above described method is performed and includes forming a polysilicon isolation layer overlying the upper surface of the semiconductor layer and extending from a position proximate the P+ anode region over the shallow P well region, overlying the p-n junction, and extending over a portion of the N well region; wherein a portion of the polysilicon isolation layer overlies a portion of the ROX layer.

In another additional embodiment, the above described method is performed wherein the P well has a first doping concentration of P-type atoms, the shallow P well region has a second doping concentration of P-type atoms, and the P+ anode has a third doping concentration of P-type atoms that is greater than the second concentration and the second concentration is greater than the first concentration; and the N well has a first doping concentration of N-type atoms, the shallow N well region has a second concentration of N-type atoms, and the N+ anode region has a third concentration of N-type atoms that is greater than the second concentration and the second concentration is greater than the first concentration.

Although the illustrative embodiment and its advantages have been described in detail, it should be understood that various changes, substitutions, and alterations can be made herein without departing from the spirit and scope of the invention as defined by the appended claims. For example, alternate materials, implant doses and temperatures may be implemented.

Moreover, the scope of the present application is not intended to be limited to the particular embodiments of the process, machine, manufacture, composition of matter, means, methods, and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor device comprising:
a P well region disposed within a semiconductor substrate having an upper surface;
an N well region disposed within the semiconductor substrate adjacent to the P well region and forming a p-n junction with the P well region;
a P+ region forming an anode at the upper surface of the semiconductor substrate in the P well region;
an N+ region forming a cathode at the upper surface of the semiconductor substrate in the N well region; and
an isolation structure formed over the upper surface of the semiconductor substrate between the anode and the cathode and electrically isolating the anode and cathode;
wherein the isolation structure further comprises a first dielectric layer overlying a portion of the upper surface of the semiconductor substrate, and a second dielectric layer overlying a portion of the first dielectric layer and a portion of the upper surface of the semiconductor substrate.

2. The semiconductor device of claim 1, wherein the P well region further comprises a shallow P well region disposed at the upper surface of the semiconductor substrate surrounding the P+ region.

3. The semiconductor device of claim 2, wherein the N well region further comprises a shallow N well region disposed at the surface of the semiconductor substrate, surrounding the N+ region.

4. The semiconductor device of claim 1 and wherein the first dielectric layer further comprises a layer of resurf oxide (ROX).

5. The semiconductor device of claim 4, wherein the second dielectric layer further comprises a layer of resist protect oxide (RPO).

6. The semiconductor device of claim 4, wherein the ROX layer extends over the upper surface of the semiconductor substrate from the shallow N well region in the N well region, over the p-n junction, and over the shallow P well region to a point proximal to the P+ region.

7. The semiconductor device of claim 4, wherein the isolation structure further comprises a polysilicon layer over the upper surface of the semiconductor substrate overlying the shallow P well region and the p-n junction.

8. The semiconductor device of claim 7, wherein the polysilicon layer extends over the N well region and over a portion of the ROX layer.

9. The semiconductor device of claim 4, wherein the P well region has a first doping concentration of P-type atoms, the shallow P well region has a second doping concentration of P-type atoms, and the P+ region has a third concentration of P-type atoms, and the third concentration is higher than the second concentration, which is higher than the first concentration.

10. The semiconductor device of claim 4, wherein the N well region has a first doping concentration of N-type atoms, the shallow N well region has a second doping concentration of N-type atoms, and the N+ region has a third concentration of N-type atoms, and the third concentration is higher than the second concentration which is higher than the first concentration.

11. A high voltage diode structure, comprising:
a P well region in a semiconductor layer having an upper surface;
an N well region in the semiconductor layer, adjacent the P well region, and forming a p-n junction with the P well region;
a P+ anode region at the upper surface of the semiconductor layer in the P well region;
a shallow P well region in the P well region, the shallow P well region having a portion at the upper surface of the semiconductor layer, and surrounding the P+ anode region;
an N+ cathode region at the upper surface of the semiconductor layer in the N well region;
a shallow N well region in the N well region, the shallow N well region having a portion at the upper surface of the semiconductor layer, and surrounding the N+ anode region; and
an isolation structure formed entirely over the upper surface of the semiconductor layer and overlying the p-n junction, the shallow P well region, and the shallow N well region.

12. The high voltage diode structure of claim 11, wherein the isolation structure further comprises:
a resurf oxide (ROX) layer overlying the upper surface of the semiconductor layer between the P+ anode region and the N+ cathode region; and
a resist protective oxide (RPO) layer overlying at least a portion of the ROX layer and a portion of the shallow N well region.

13. The high voltage diode structure of claim 12 wherein the ROX layer extends over the upper surface of the semiconductor layer from the N well region, over the p-n junction, and over at least a portion of the shallow P well region.

14. The high voltage diode structure of claim 11, wherein the isolation structure further comprises:
a polysilicon isolation feature formed overlying the upper surface of the semiconductor layer and extending from an area proximate the P+ anode over the shallow P well region, overlying the p-n junction, and overlying at least a portion of the N well region;
a resurf oxide layer (ROX) overlying the upper surface of the semiconductor layer and extending from the shallow N well region towards the p-n junction, wherein a portion of the polysilicon isolation feature overlies a portion of the ROX layer; and
a resist protect oxide (RPO) layer overlying the upper layer of the semiconductor layer and overlying at least a portion of the shallow N well region and overlying a portion of the ROX layer.

15. The high voltage diode structure of claim 14, wherein the polysilicon isolation feature further comprises a gate polysilicon layer.

16. A method, comprising:
providing a semiconductor layer having an upper surface;
forming a P well in the semiconductor layer;
forming an N well in the semiconductor layer adjacent the P well and forming a p-n junction with the P well;
forming a shallow P-type well region in the P well, the shallow P-type well region having a portion at the upper surface of the semiconductor layer;
forming a shallow N-type well region in the N well, the shallow N-type well region having a portion at the upper surface of the semiconductor layer;
forming a P+ anode at the surface of the semiconductor layer, surrounded by the shallow P-type well region;
forming an N+ cathode at the surface of the semiconductor layer, surrounded by the shallow N-type well region; and
forming an isolation structure between the anode and the cathode, the isolation structure overlying the upper surface of the semiconductor layer.

17. The method of claim 16, wherein forming an isolation structure further comprises:
forming a resurf oxide layer (ROX) overlying the upper surface of the semiconductor layer between the P+ anode and the N+ cathode; and
forming a resist protect oxide (RPO) overlying a portion of the ROX layer and a portion of the shallow N-type well region.

18. The method of claim 17, and further comprising:
extending the ROX layer over the upper surface of the semiconductor layer from the shallow N-type well region over the p-n junction and over the shallow P-type well region to a position proximate the P+ anode.

19. The method of claim 17, and further comprising:
forming a polysilicon isolation layer overlying the upper surface of the semiconductor layer and extending from a position proximate the P+ anode region over the shallow P-type well region, overlying the p-n junction, and extending over a portion of the N well region;
wherein a portion of the polysilicon isolation layer overlies a portion of the ROX layer.

20. The method of claim 16, wherein the P well has a first doping concentration of P-type atoms, the shallow P-type well region has a second doping concentration of P-type atoms, and the P+ anode has a third doping concentration of P-type atoms that is greater than the second concentration and the second concentration is greater than the first concentration; and
the N well has a first doping concentration of N-type atoms, the shallow N-type well region has a second doping concentration of N-type atoms, and the N+ anode region has a third concentration of N-type atoms that is greater than the second concentration and the second concentration is greater than the first concentration.
